(19) United States
(12) Patent Application Publication
(10) Pub. No.: US 2018/0142349 A1
(43) Pub. Date: May 24, 2018

(54) Method for Depositing Zinc Oxide on a Substrate

(71) Applicant: Universität ULM, Ulm (DE)

(72) Inventors: Anton Reiser, Biberbach (DE); Manfred Madel, Ulm (DE); Florian Huber, Schnürpflingen (DE); Klaus Thonke, Ulm (DE)

(21) Appl. No.: 15/576,215

(22) PCT Filed: May 20, 2016
(86) PCT No.: PCT/EP2016/061418

§ 371 Date: Feb. 8, 2018

(30) Foreign Application Priority Data
May 21, 2015 (DE) 10 2015 209 358.1

(51) Int. Cl. C23C 16/40

(52) U.S. Cl. CPC C23C 16/407

(57) ABSTRACT

A method for depositing zinc oxide on a substrate is disclosed. In an embodiment, the method includes reducing, in a first stage, a source material comprising zinc oxide to zinc which is gaseous at reaction conditions by contacting the source material with a gaseous reducing agent, transporting, in a second stage locally separate from the first stage, the gaseous zinc to the substrate, wherein the gaseous zinc is converted to zinc oxide by adding an oxidizing agent; and depositing the zinc oxide on a surface of the substrate, wherein the gaseous reducing agent is methane or a thermal decomposition product of at least one precursor, which is thermally decomposed at the reaction conditions of the first stage so that methane, methyl radicals and/or acetone is released.

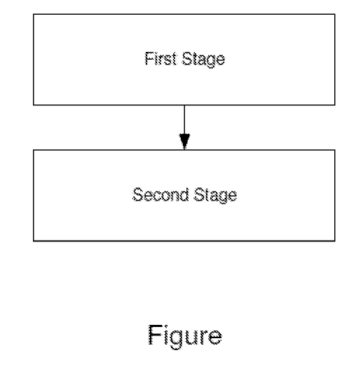

This patent application is a national phase filing under section 371 of PCT/EP2016/061418, filed May 20, 2016, which claims the priority of German patent application 10 2015 209 358.1, filed May 21, 2015, each of which is incorporated herein by reference in its entirety.

### TECHNICAL FIELD

The invention relates to a method for depositing zinc oxide on a substrate.

### BACKGROUND

Methods for the deposition of zinc oxide known from the prior art, in particular metalorganic vapor phase epitaxy, magnetron sputtering, plasma assisted methods, molecular beam epitaxy, and other methods, which allow for the achievement of high purity or the good control of the doping, are characterized in that they are much more expensive to perform.

Alternatively, there are low-cost purely wet-chemical low-temperature methods for the production especially of polycrystalline ZnO layers or ZnO nanostructures, which are very inexpensive, but only provide lower quality material with a high density of crystal defects, and are difficult to control.

The previously known methods are thus characterized, on the one hand, by the fact that they are either significantly more expensive and more complicated to implement and, in some cases, have low growth rates, and, on the other hand, that a significantly poorer control of the properties of the layers produced (especially in wet-chemical processes) is possible.

In the known CVD method for the deposition of zinc oxide layers in which metallic zinc is used, in addition sometimes highly toxic and corrosive oxygen sources such as nitrogen dioxide are used, which represents a further disadvantage.

### SUMMARY OF THE INVENTION

The present invention relates to a method for depositing zinc oxide on a substrate using zinc oxide as the source material.

Embodiments of the present invention provide a method for the deposition of zinc oxide on substrates, which avoids the disadvantages mentioned above. In various embodiments, the method is inexpensive, easy to control, and enable the relatively fast production of conductive and optically transparent zinc oxide layers that can be transferred to larger scales.

In further embodiments the zinc oxide is reduced in a first stage to elemental zinc, the elemental zinc generated in situ is passed in vapor form to a substrate to be coated and exposed there to an oxidizing atmosphere. In this case, a deposition of zinc oxide takes place on a surface of the substrate. Further embodiments of the invention reduce zinc oxide used as the source material to elemental zinc, wherein either methane or another reducing agent is used. The reducing agent may release methane and/or methyl radicals by thermal decomposition under the conditions prevailing during the reduction. In various embodiments the resulting zinc gas stream is used in another part of the reactor with the supply of oxygen or other oxidizing substances directly for the deposition of crystalline zinc oxide layers.

### BRIEF DESCRIPTION OF THE DRAWINGS

For a more complete understanding of the present invention, and the advantages thereof, reference is now made to the following description taken in conjunction with the accompanying drawing, in which:

FIGURE shows a method for depositing zinc oxide on a substrate according to an embodiment.

### DETAILED DESCRIPTION OF ILLUSTRATIVE EMBODIMENTS

Embodiments of the present invention concerns a process for the deposition of zinc oxide on a substrate, in which a source material consisting of zinc oxide or a source material containing zinc oxide is reduced in a first stage to zinc gaseously present under the reaction conditions by bringing the source material into contact with a gaseous reducing agent. The gaseous reducing agent is in this case selected from methane or from thermal decomposition products of at least one precursor which is thermally decomposed at the reaction conditions prevailing in the first stage, whereby methane and/or methyl radicals and/or acetone are released. In a second stage, the gaseous zinc is transported to the substrate, where it is converted into zinc oxide under oxidative conditions and deposited as a preferably crystalline (in particular hexagonal) zinc oxide on a surface of the substrate.

Further embodiments provide to deposit zinc oxide semiconductor layers on various substrates (especially sapphire, ZnO, gallium nitride, but also silicon, glass, etc.) very well controlled and in high crystalline and electronic quality with very little effort. In particular, this makes it possible to produce transparent electronic contacts (n-type, e. g. on all possible types of solar cells, photodetectors, thin-film transistors (e. g. TFT on displays) and other electronic components). Furthermore, these layers are of great importance for sensor applications for gases, chemicals, proteins etc.

Various other embodiments provide the selection of source materials and precursors or the underlying chemical processes for the growth of ZnO layers. The source material used is, for example, inexpensive ZnO powder instead of metallic zinc or organometallic compounds, as in the established processes. The reduction of the ZnO to Zn steam does not occur, as is often the case with the growth of nanostructures, with an admixture of the graphite powder (which is difficult to control during the growth process) but via a gaseous reducing agent.

Using the reducing agents, the overall reaction and thus the crystal growth can be controlled via a very simple and thus cost-effective growth process. The entire process can advantageously be carried out in a simple tube furnace. Compared to other CVD growth methods using pure zinc as the source material, the oxygen required for ZnO growth can be introduced directly into the growth apparatus with the gaseous reducing agent without the need for additional connections or gas inlets. This allows the process to be easily scaled up for larger diameters.

A decisive advantage is that as a reducing agent uncritical chemical compounds such, e.g., isopropanol can be used. Up to now, CVD growth with pure zinc as a source material has mostly been based on toxic gases such as nitrogen dioxide. In addition, by the use of inert gases as transport gas, the concentration of the hydrocarbon can be kept below the concentrations critical for ignition and thus uncontrolled combustion reactions are reduced in the system. As a result, the risk of fire is kept very low. Growth can also be achieved at normal pressure, which means that no vacuum technology is required. At approx. 800° C., the growth temperature can be chosen significantly higher than with CVD processes with pure zinc as a source substance, at which the temperature in the furnace must be kept below the zinc melting point (420° C.). This results in a better crystalline quality of the resulting layers.

With electron microscopy, X-ray measurements and low temperature photoluminescence very good crystal quality and purity of the layers could be demonstrated.

In various embodiments the active reducing agent used to reduce zinc oxide to zinc is either introduced directly as methane gas or obtained from a precursor material. This precursor material decomposes into the active reducing agent methane or methyl radicals in the first stage, in which zinc oxide is reduced to zinc. If a precursor is used instead of methane in the first stage, this precursor is thermally decomposed into an active reducing agent. The first stage of the process is therefore to be operated at temperatures that allow thermal decomposition of the precursor material to methane or methyl radicals and/or acetone. The methane or the products produced during decay are passed through the ZnO powder and are then responsible for reducing the ZnO source material into elemental zinc.

According to a preferred embodiment, the precursor(s) has/have a functional group in which a hydrogen atom is bonded to a carbon atom, in particular at least one methane group, ethyl group and/or methyl group.

More preferably, the precursor(s) is/are liquid or gaseous under normal conditions.

According to a particularly preferred embodiment, the precursor(s) is or are selected from the group consisting of aliphatic, aromatic or heterocyclic hydrocarbons, preferably alkanes, alkenes or alkynes, aliphatic or aromatic alcohols.

In principle, all hydrocarbons or other chemical compounds such as alcohols which have a functional group consisting of carbon and hydrogen (e. g. a methine, ethyl or methyl group) are suitable as reducing agents. While the reducing agent in the high-temperature furnace is transported to the ZnO source material, the thermally induced decomposition of the reducing agent in one or more intermediate reactions produces methane (CH₄) and CH₃ radicals, or CH₄ is fed directly. In the event that oxygen-containing precursors are used, the release of acetone is also possible, which also acts as a reducing agent.

Alkanes such as methane or aliphatic alcohols such as isopropanol or ethanol have proven to be particularly effective as precursor materials.

The reducing agent can either be passed directly into the growth system in gaseous form, or fed via a bubbler. In the latter method, the inert carrier gas is first passed through a bubbler system before being directed to the growth system. As a result, the reducing agent is added to the carrier gas, whereby this also enters the system.

Preferably, the first stage, i.e., the reduction of zinc oxide to zinc, depending on the process pressure is carried out at temperatures from 300° C. to 1200° C., preferably from 500° C. to 1000° C., more preferably from 700° C. to 950° C.

The gaseous elementary zinc is transported via a carrier gas (inert gas, e. g. argon or nitrogen) to the substrate on which zinc oxide growth takes place with the addition of oxygen or other suitable oxidizing agents.

Depending on the process pressure, the second stage of the growth is preferably carried out at temperatures of from 300° C. to 1200° C., preferably from 450° C. to 950° C., more preferably from 650° C. to 900° C.

Depending on the temperatures of the first and second stages, the first and/or second stage can be carried out at pressures of 10⁻⁵ mbar to 3000 mbar, preferably 500 mbar to 1500 mbar, particularly preferably 900 mbar to 1100 mbar, in particular at ambient pressure.

According to a particularly preferred embodiment, the process according to the invention is carried out in a gas stream, wherein the at least one precursor and/or the gaseous reducing agent is transported to the source material with the gas stream and/or gaseous zinc is transported from the first stage to the second stage by the gas stream.

Thus, both the source material and the substrate are preferably located together in the gas stream, the substrate being arranged downstream relative to the source material in the gas stream.

A further preferred configuration provides that the gas of the gas stream is a gas which, under the conditions prevailing in the first and/or second stage, is chemically inert to the at least one precursor and/or reducing agent or a mixture of several of these gases, preferably selected from the group consisting of argon, nitrogen, helium and mixtures of at least two of the gases mentioned above.

Alternatively, it is also possible for the at least one precursor to be introduced separately from the gas stream into the first stage, preferably in the gaseous state.

In the event, for example, that a precursor which is liquid under normal conditions is used, it can preferably be converted into the gas phase, for example, by means of conventional evaporation processes, and in this way fed to the first stage.

In the method according to the invention, in the case where the at least one precursor is flammable under the conditions prevailing in the first and/or second stage, the concentration of the at least one precursor in the first stage is particularly preferably set below the concentration critical for ignition.

In the second stage, the oxidative conditions can be achieved by the application of a gaseous oxidant, preferably oxygen, air and/or H₂O₂ under the conditions prevailing in the second stage.

In particular, the source material is used in powder form, in particular that the source material is zinc oxide powder, for which a certain sublimation rate can be achieved depending on grain size and density. The smaller the medium grain size of the ZnO powder is chosen, the larger the surface area of the zinc oxide and the better the material can be sublimated under the specified reaction conditions.

The inventive method can be carried out in a preferred manner in a high-temperature furnace, in particular in a tube furnace, wherein the first and the second stage are spatially separated from each other in the furnace and can be controlled separately in temperature.

As the substrate material which can be coated by the method of the present invention, substantially all solid materials which maintain their state of aggregation at the conditions prevailing in the second stage and do not decompose are suitable. Inorganic materials with a sufficiently high melting point are particularly suitable for this purpose. Particularly preferred, metals, semi-metals, semiconductors, metal oxides (e. g. ZnO) or ceramic materials can be coated with the method according to the invention. Materials selected from the group consisting of sapphire, gallium nitride, silicon, germanium, aluminum oxide, glass and crystalline films made of metals or metal oxides are particularly suitable.

More preferably, simultaneous doping of the depositing zinc oxide film can be carried out in the second stage. For this purpose, a corresponding dopant is added to the atmosphere of the second stage. In particular, an n-doping process is particularly suitable for doping the zinc oxide layer, in particular by incorporating aluminum, indium or gallium atoms into the zinc oxide layer. For this purpose, a conventional, state-of-the-art aluminum, indium or gallium compound is added to the atmosphere in the second stage for doping the zinc oxide layer that is deposited.

The inventive method is preferably suitable for the production of non-conductive layers, conductive transparent layers (transparent conductive oxides, “TCO”), electrical contacts or conductor structures on substrates, easily etchable sacrificial layers in multilayer systems, nano- or macrostructures for sensor applications, thin-film transistors (TFT on displays), Schottky diodes and field effect transistors.

1-16. (canceled)

17. A method for depositing zinc oxide on a substrate, the method comprising:
reducing, in a first stage, a source material comprising zinc oxide to zinc which is gaseous at reaction conditions by contacting the source material with a gaseous reducing agent;
transporting, in a second stage locally separate from the first stage, the gaseous zinc to the substrate, wherein the gaseous zinc is converted to zinc oxide by adding an oxidizing agent; and
depositing the zinc oxide on a surface of the substrate,
wherein the gaseous reducing agent is methane or a thermal decomposition product of at least one precursor, which is thermally decomposed at the reaction conditions of the first stage so that methane, methyl radicals and/or acetone is released.

18. The method according to claim 17, wherein the at least one precursor has a functional group in which a hydrogen atom is bonded to a carbon atom.

19. The method according to claim 17, wherein the at least one precursor is liquid or gaseous under normal conditions.

20. The method according to claim 17, wherein the at least one precursor is selected from the group consisting of aliphatic, aromatic and heterocyclic hydrocarbons.

21. The method according to claim 17,
wherein the first stage is carried out at temperatures of 300° C. to 1200° C., and
wherein the second stage is carried out at temperatures of 300° C. to 1200° C.

22. The method according to claim 17, wherein the first and/or second stage is carried out at pressures of 10⁻⁵ mbar to 3000 mbar.

23. The method according to claim 17, wherein the method is carried out in a gas stream, wherein the at least one precursor and/or the gaseous reducing agent is transported to the source material with the gas stream and/or gaseous zinc is transported with the gas stream from the first stage to the second stage.

24. The method according to claim 23, wherein a gas of the gas stream is in the conditions prevailing in the first and/or second stage a gas or a mixture of several gases which is chemically inert over the at least one precursor and/or the reducing agent.

25. The method according to claim 17, wherein the at least one precursor is fed separately from a gas stream in the first stage.

26. The method according to claim 17, wherein, when the at least one precursor is flammable under the conditions prevailing in the first and/or second stage, a concentration of the at least one precursor in the first stage is set below that for an inflammation critical concentration.

27. The method according to claim 17, wherein the oxidizing agent introduced in the second stage, in the conditions prevailing in the second stage, is gaseous.

28. The method according to claim 17, wherein the source material comprises powder.

29. The method according to claim 17, wherein the method is carried out in a high-temperature furnace.

30. The method according to claim 17, wherein the substrate comprises metals, semi-metals, semiconductors, metal oxides or ceramic materials.

31. The method according to claim 17, further comprising introducing at least one dopant for incorporating impurities.

32. The method according to claim 17, wherein the method forms nonconductive layers, conductive transparent layers, electrical contacts or conductor structures on substrates.
